(19) United States
(12) Patent Application Publication
(10) Pub. No.: US 2008/0105909 A1
(43) Pub. Date: May 8, 2008

(54) Pixel circuit included in CMOS image sensors and associated methods

(76) Inventors: Seog-Heon Ham, Suwon-si (KR); Bo-Kyung Kim, Seoul (KR); Young-Cheol Chae, Seoul (KR); Gun-Hee Han, Goyang-si (KR)

Correspondence Address: LEE & MORSE, P.C., 3141 FAIRVIEW PARK DRIVE, SUITE 500, FALLS CHURCH, VA, 22042, US

(21) Appl. No.: 11/976,658

(22) Filed: Oct. 26, 2007

(30) Foreign Application Priority Data
Nov. 8, 2006 (KR) 10-2006-0110119

(51) Int. Cl. H01L 27/146; H01L 31/18

(52) U.S. Cl. 257/292; 438/59; 257/E27.133

(57) ABSTRACT

Example embodiments relate to a pixel structure of a CMOS image sensor, and associated methods. The pixel structure may include a substrate of a first-conductivity, a photodiode region of a second conductivity in the first-conductivity substrate, and a capacitor electrode on the second-conductivity photodiode region.

### BACKGROUND OF THE INVENTION

1. Field of the Invention

Example embodiments relate to complementary metal-oxide-semiconductor (CMOS) image sensors, and associated methods. More particularly, example embodiments relate to pixel circuits included in CMOS image sensors, and associated methods.

2. Description of the Related Art

Generally, CMOS image sensors may be employed in various devices, e.g., mobile cameras or digital still cameras. The CMOS image sensors may take images from in fields of vision, may convert the images into electrical signals, and then transfer the electrical signals to digital signal processors. The digital signal processor may function to control signal processing operations with color image data output from a charge-coupled device (CCD), so that the color image data may be expressed in a display unit, i.e., a liquid crystal display (LCD) panel.

A typical CMOS image sensor may generally include a pixel sensor array arranged in a matrix. Each pixel sensor may be formed with an optical device for converting light into an electric signal, e.g., a photodiode. Further, there have recently been developments in smart image sensors or silicon retinas to apply CMOS image sensors. As such, there may be a requirement to adjust optical sensitivity or spectrum response rates for every pixel. Accordingly, if a pixel includes a device for adjusting optical sensitivity or spectrum response rate, an area for installing the photodiode may be reduced, and thus, the brightness of an image may be degraded.

### SUMMARY OF THE INVENTION

Example embodiments are therefore directed to a pixel circuit of a CMOS image sensor and associated methods, which may substantially overcome one or more of the problems due to the limitations and disadvantages of the related art.

Example embodiments relate to a pixel circuit of a CMOS image sensor having a device and method for adjusting an optical sensitivity.

Example embodiments relate to a pixel circuit of a CMOS image sensor having a device and method for adjusting a spectrum response rate.

Example embodiments relate to a pixel circuit of a CMOS image sensor and method capable of controlling optical sensitivity.

Example embodiments relate to a pixel circuit of a CMOS image sensor and method capable of controlling spectrum response rate.

At least one of the above and other features of example embodiments may provide a pixel structure of a CMOS image sensor, having a substrate of a first-conductivity, a photodiode region of a second conductivity in the first-conductivity substrate, and a capacitor electrode on the second-conductivity photodiode region.

The capacitor electrode may be formed to substantially cover the second-conductivity photodiode region.

The capacitor electrode may be formed to partially cover the second-conductivity photodiode region. The second-conductivity photodiode region may be partially covered in a bi-directionally extending form of fingers. The second-conductivity photodiode region may be partially covered with a plurality of openings.

The capacitor electrode may be formed of a transparent conductive film coupled to a sensitivity control signal. The transparent conductive film may be polysilicon.

The pixel structure may further include a floating diffusion layer adjacent to the second-conductivity photodiode region.

The pixel structure may further include a dielectric film on the second-conductivity photodiode region, and the capacitor electrode may be positioned on the dielectric film.

The pixel structure may be a pixel circuit. The pixel circuit may include a first transistor connected to a first node through one of source and drain electrodes and to an output node through the other source and drain electrodes, and receives a row selection signal through a gate electrode, a second transistor connected to a first voltage through one of the source and drain electrodes and to a second node through the other source and drain electrodes, and receives a reset control signal through a gate electrode, a third transistor connected to a first power source through one of the source and drain electrodes to the first node through the other source and drain electrodes, and to the second node through a gate electrode, and a photodiode connected between a second voltage and the second node, to conduct a photoelectric conversion.

The second transistor and the third transistor may be connected between the first power source and the first node in series.

At least one of the above and other features of example embodiments may provide a method of forming a pixel structure in a CMOS image sensor, including forming a substrate of a first-conductivity, forming a photodiode region of a second conductivity in the first-conductivity substrate, and forming a capacitor electrode on the second-conductivity photodiode region.

The method may further include connecting a first transistor to a first node through one of source and drain electrodes and to an output node through the other source and drain electrodes, and may receive a row selection signal through a gate electrode, connecting a second transistor to a first voltage through one of the source and drain electrodes and to a second node through the other source and drain electrodes, and may receive a reset control signal through a gate electrode, connecting a third transistor to a first power source through one of the source and drain electrodes to the first node through the other source and drain electrodes, and to the second node through a gate electrode, and connecting a photodiode between a second voltage and the second node, to conduct a photoelectric conversion.

At least one of the above and other features of example embodiments may provide a method of operating a pixel structure in a CMOS image sensor. The pixel structure may include a first transistor connected to a first node through one of source and drain electrodes and to an output node through the other source and drain electrodes, a second transistor connected to a first voltage through one of the source and drain electrodes and to a second node through the other source and drain electrodes, a third transistor connected to a first power source through one of the source and drain electrodes to the first node through the other source and drain electrodes and to the second node through a gate electrode, and a photodiode connected between a second voltage and the second node. The method may include supplying a row selection signal through a gate electrode of the first transistor, supplying a reset control signal through a gate electrode of the second transistor, and supplying a voltage to one of the first and second nodes in accordance with the reset control signal and the row selection signal.

If the reset control signal is high while the row selection signal is high, increasing a voltage level of the second node and transferring the voltage to the first node via the second and third transistors to provide a reset voltage VRES.

If the reset control signal is low while the row selection signal is high, applying an image signal photoelectrically converted from the photodiode to the second node via the third and first transistors to provide an image signal voltage VSIG.

### BRIEF DESCRIPTION OF THE DRAWINGS

The above and other features and advantages of example embodiments will become more apparent to those of ordinary skill in the art by describing in detail example embodiments thereof with reference to the attached drawings, in which:

FIG. 1 illustrates a block diagram of a CMOS image sensor including a pixel circuit in accordance with an example embodiment;

FIG. 2 illustrates a diagram of an arrangement of color filters in the CMOS image sensor of FIG. 1;

FIG. 3 illustrates a circuit diagram of a unit pixel sensor arranged on an ARS array shown in FIG. 1;

FIG. 4 illustrates a pixel circuit of the CMOS image sensor in accordance with an example embodiment;

FIG. 5 illustrates a sectional diagram of an optical detector of FIG. 4 in a semiconductor substrate;

FIG. 6 illustrates a graph of capacitance-voltage characteristics of MOS capacitor;

FIGS. 7A through 7C illustrate diagrams of top patterns of a capacitor electrode shown in FIG. 4;

FIG. 8 illustrates a sectional diagram of another structure of a photosensor shown in FIG. 4;

FIG. 9 illustrates a pixel circuit of the CMOS image sensor in accordance with another example embodiment; and

FIG. 10 illustrates a timing diagram of reset and transmission control signals operating in the pixel circuit shown in FIG. 9.

### DETAILED DESCRIPTION OF THE INVENTION

Korean Patent Application No. 10-2006-0110119 filed on Nov. 8, 2006, in the Korean Intellectual Property Office, and entitled: “Pixel Circuit of CMOS Image Sensor Capable of Controlling Sensitivity Thereof,” is incorporated by reference herein in its entirety.

Example embodiments will now be described more fully hereinafter with reference to the accompanying drawings. The invention may, however, be embodied in different forms and should not be construed as limited to the embodiments set forth herein. Rather, these example embodiments are provided so that this disclosure will be thorough and complete, and will fully convey the scope of the invention to those skilled in the art.

In the CMOS image sensor according to example embodiments, a pixel circuit may include a photodiode for photoelectric conversion and a capacitor for adjusting a voltage level of an image signal, so as to adjust a voltage level of the image signal in accordance with a voltage level of the sensitivity control signal. Moreover, a transparent conductive film made of polysilicon, for example, may be formed as a capacitor electrode of a MOS capacitor C_{SCG}, so as to minimize any distortion of photoelectric effect by the photodiode. In other words, the capacitor electrode of the MOS capacitor, which may be formed of transparent conductive film of polysilicon, may be patterned to partially cover the photodiode, in order to maximize capacitance thereof.

Accordingly, example embodiments may provide the capacitor electrode of a variable capacitor to be formed on the photodiode and a lightly-doped well for photoelectric conversion. Further, the lightly-doped well may be used as a bottom electrode of the variable capacitor, so that there may not be any need for additional region for the variable capacitor in a substrate. Further, as the top electrode of the variable capacitor may be fabricated along with a process for a gate electrode of a transistor, there is no need for additional mask or processing step. Hence, it is effective to control optical sensitivity and/or spectrum response rate at every pixel for silicon retinas or smart image sensors.

Further, in an alternative example embodiment, the capacitor electrode of the variable capacitor may be formed to partially cover the photodiode, so as to increase a capacitance variation range of the capacitor. Moreover, the partial coverage of the top electrode of the variable capacitor over the photodiode may enhance the optical sensitivity of the photodiode due to the top face of the photodiode being directly exposed to light.

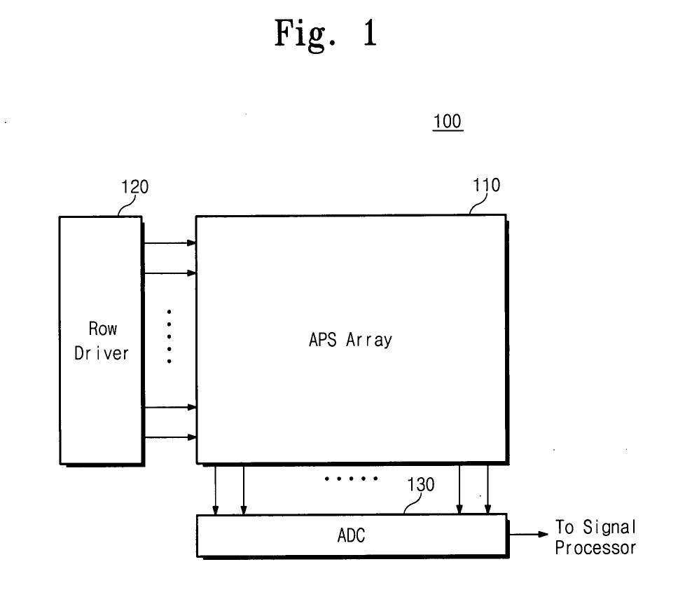

FIG. 1 illustrates a block diagram of a CMOS image sensor 100 including a pixel circuit in accordance with an example embodiment. Referring to FIG. 1, the CMOS image sensor 100 may include an active pixel sensor (APS) array 110, a row driver 120, and an analog-to-digital converter (ADC) 130. The APS array 110 may include pixel circuits arranged in plurality of rows and columns. A detailed structure of the pixel circuit will be described in detail later. The CMOS image sensor 100 may further include a controller (not shown) for generating address signals to select pixel circuits and output image signals sensed from the APS array 110. The row driver 120 may select rows of the APS array 110 in sequence. The ADC 130 may convert an analog signal, which may be sensed from the APS array 110, into a digital signal to be provided into a signal processor.

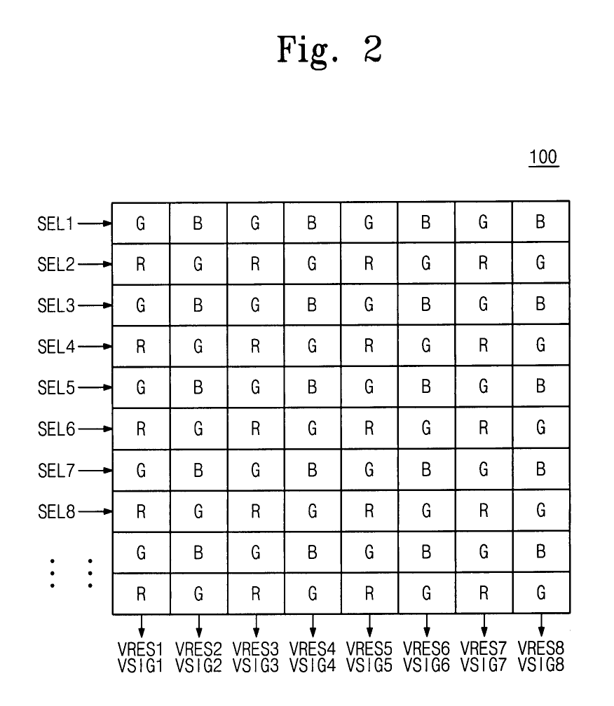

If the CMOS image sensor 100 is a color charged-coupled device (CCD) (as shown in FIG. 2), color filters may be disposed to accept specific color components on each pixel of the APS array 110. At least three color filters may be formed to compose a color signal. The most general color filter array may be structured in a pattern, i.e., Bayer pattern, where two rows may be repeatedly arranged in unit. For example, one row may be arranged with repeating two colors of red (R) and green (G); and the other row may be arranged with repeating two colors of green (G) and blue (B). In an example embodiment, G color filters most relevant to a luminance signal may be arranged on all rows while R and B color filters may alternately be arranged by rows, which may enhance resolution of luminance. It should be appreciated that the color filter may be arranged in different patterns.

A digital still camera, for example, may be generally equipped with a CMOS image sensor having a million or more pixels for high resolution.

The APS array 110 may generate image signals through sensing light and may convert the sensed light into electric signals by an electron optical device, e.g., a photodiode. Image signals output from the APS array 110 may be analog image signals corresponding to three colors components R, G, and B. The ADC 130 may convert an analog image signal, which may be output from the APS array 110, into a digital signal.

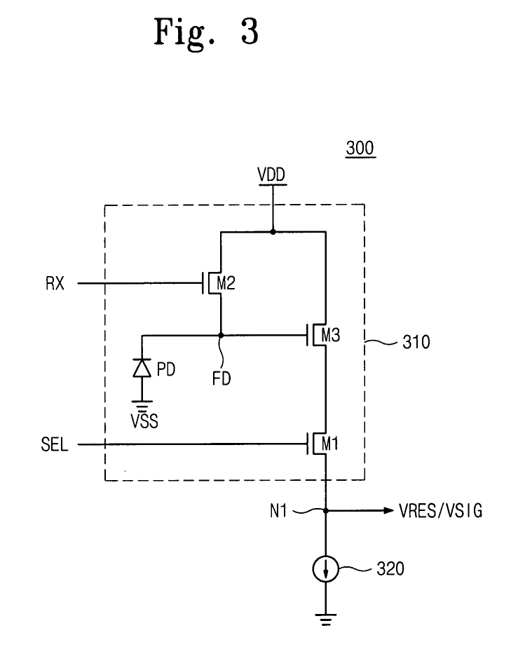

FIG. 3 illustrates a circuit diagram of a unit pixel sensor 300 arranged on the APS array 110 shown in FIG. 1. Referring to FIG. 3, the pixel sensor 300 may include a pixel circuit 310 formed of three metal-oxide-semiconductor field effect transistors (MOSFETs) M1˜M3, a single photodiode PD and a bias circuit 320. A plurality of the pixel circuits 310 may be arranged in a matrix of plural rows and columns. It should be appreciated that a plurality of bias circuits 320 may be employed in the pixel sensor 300. For example, a plurality of bias circuits 320 may be arranged around tops and bottoms of the pixel circuits 310 so as to bias a node N1.

The pixel circuit 310 may operate by converting a sensed analog image signal into a digital signal. When a reset control signal RX is high while a row selection signal SEL is high, a transistor M2 may be turned on to apply a voltage from a floating diffusion node (FD) to a source node, e.g., a source follower transistor M3. Further, as the row selection signal SEL is high turns on a transistor M1, a voltage of the source node of the source follower transistor M3 may be provided to the ADC 130 through the node N1 as a reset signal VRES.

Alternatively, when the reset control signal RX is low while the row selection signal SEL is high, an image signal photoelectrically converted from the photodiode PD may be applied to the node FD, and provided to the ADC 130 through the transistors M3 and M1 as an analog image signal voltage VSIG. By way of the operation of the pixel circuits 310, the reset signals VRES1˜VRES8 and the analog image signal voltages VSIG1˜VSIG8 may be output from pixel sensors 300, which may each be coupled to rows of the APS array 110 whenever the row selection signals SEL1˜SEL3 are activated in sequence.

The ADC 130 may output a digital signal corresponding to a voltage gap between the reset signal VRES and the analog image signal voltage VSIG. The digital signal may be provided to a digital signal processor, and may be converted into a drive signal suitable for driving a display unit, e.g., an LCD.

It should be appreciated that the CMOS image sensor 100 may further include a capacitor in the pixel circuit 310 so as to easily adjust optical sensitivity and/or a spectrum response rate every pixel.

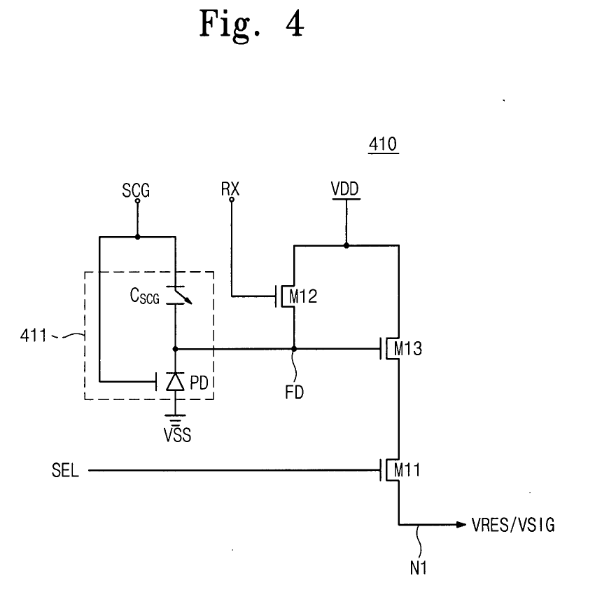

FIG. 4 illustrates a pixel circuit 410 in accordance with an example embodiment. Referring to FIG. 4, the pixel circuit 410 may include MOS transistors M11˜M13 and an optical detector 411. A drain of the transistor M12 may be coupled to a power source voltage VDD, and a source of the transistor M12 may be connected to a node FD. A gate of the MOS transistor M12 may be coupled to a reset control signal RX. The transistors M13 and M11 may be connected between the power source voltage VDD and a node N1 in series. A gate of the transistor M13 may be connected to the node FD. A gate of the transistor M11 may be coupled to a row selection signal SEL.

The optical detector 411 may include a photodiode PD and a MOS capacitor C_{SCG}. An end of the MOS capacitor C_{SCG} may be coupled to a sensitivity control signal SCG and the other end of the MOS capacitor C_{SCG} may be coupled to the photodiode PD. The photodiode PD may be connected between the MOS capacitor C_{SCG} and a ground voltage VSS.

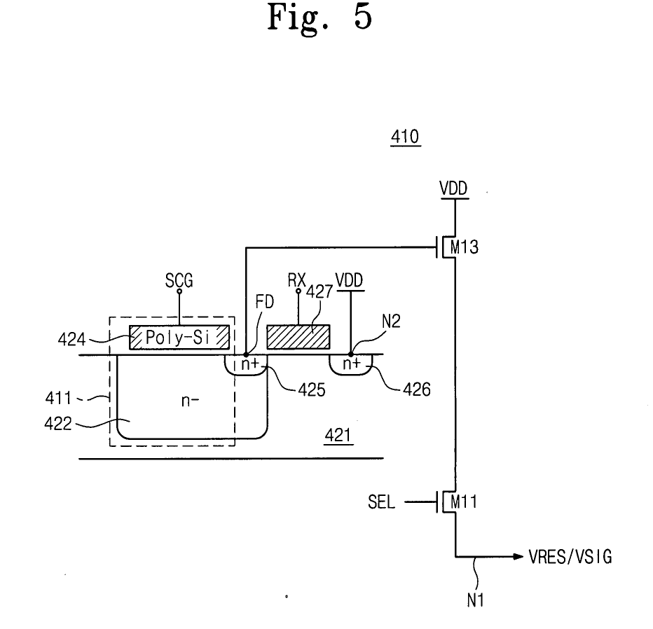

FIG. 5 illustrates a sectional diagram of the optical detector 411, e.g., a photodiode PD of FIG. 4, in a semiconductor substrate. Referring to FIG. 5, the photodiode PD may be formed as a P-N junction diode between a P-type semiconductor substrate 421 and a lightly-doped N-type impurity well 422. The MOS capacitor C_{SCG} may be formed in a vertical structure at a part of the region occupied by the photodiode PD. Further, in forming the MOS capacitor C_{SCG}, an insulation film, e.g., a dielectric film (not shown), may be first formed on top of the lightly-doped well 422, and then gate electrodes 427 of the MOS transistors M11˜M13 may be formed along with top electrodes 424 (i.e., capacitor electrodes) of the MOS capacitors C_{SCG} coupled to the sensitivity control signal SCG. The lightly-doped well 422 may operate as the bottom electrodes of the MOS capacitors C_{SCG}.

The capacitor electrode 424 of the MOS capacitor C_{SCG}, coupled to the sensitivity control signal SCG, may be formed of, for example, but not limited to, a transparent conductive film, in order to transmit external light, which may be absorbed into the lightly-doped well 422 (i.e., photodiode region). In an example embodiment, the capacitor electrode 424 may be formed of a polysilicon. It should be appreciated that other materials may be used as long as the material possesses proper conductivity and/or optical transmittance.

Further, as shown in FIG. 5, N-type wells 425 and 426 may be formed in the P-type semiconductor substrate 421. The gate of the MOS transistor M13 may be connected to the node FD formed in the well 425. A power source voltage VDD may be connected to a node N2 formed in the well 426. Thus, the well 426 may serve as the floating diffusion layer, which may be adjacent to the lightly-doped well 422 or photodiode region.

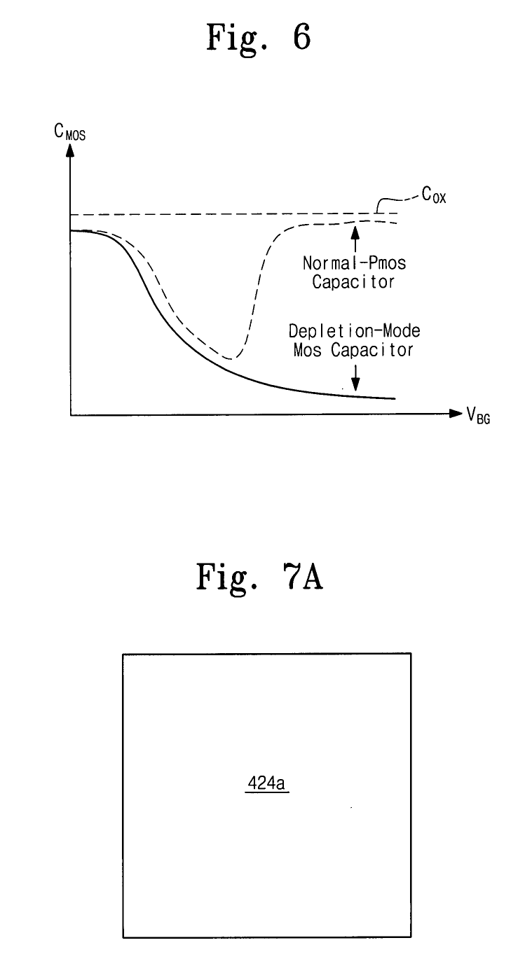

FIG. 6 illustrates a graph of capacitance-voltage characteristics of the MOS capacitor C_{SCG}. As shown in FIG. 6, V_{SG} may represent a voltage between the node FD and the capacitor electrode 424, and C_{MOS} may represent a capacitance of the MOS capacitor C_{SCG}. C_{OX} may represent an ideal capacitance if ideal capacitors existed at the top and bottom of the insulation film formed on the lightly-doped well 422.

Further, in a general P-type capacitor, a capacitance of the P-type capacitor may be reduced when a voltage across the capacitor becomes higher. In addition, the P-type capacitor may operate in an inversion mode varying close to the C_{OX} capacitance when the voltage across the capacitor reaches a predetermined level. Further, as the voltage V_{SG} increases, the MOS capacitor C_{SCG} may operate in a charge depletion mode, gradually decreasing in capacitance.

Using such characteristics of the MOS capacitor C_{SCG}, the sensitivity control signal SCS applied to the capacitor electrode 424 may vary the capacitance between the node FD and the capacitor electrode 424. As such, control of the optical sensitivity and/or spectrum response rate for every pixel may be achieved.

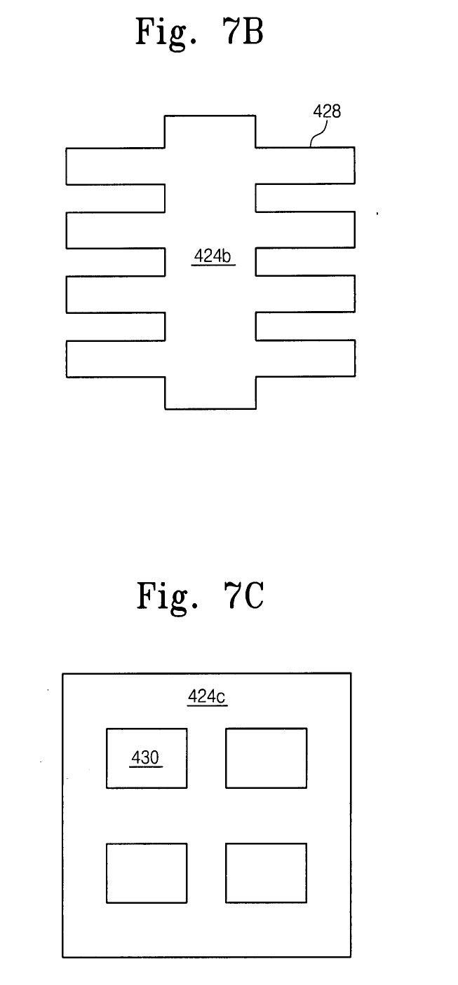

FIGS. 7A through 7C illustrate diagrams of top patterns of the capacitor electrode 424 shown in FIG. 4. Referring to FIG. 7A, a capacitor electrode 424a made of polysilicon may be formed to cover all (or substantially all) over the lightly-doped well 422, e.g., the photodiode region. In another example embodiment, FIG. 7B illustrates a capacitor electrode 424b having a finger type 428 extending bi-directionally so as to partially cover the lightly-doped well 422 of the photodiode region. In another example embodiment, FIG. 7C illustrates a capacitor electrode 424c having a plurality of openings 430 formed on top of the lightly-doped well 422 of the photodiode region. Although the example embodiment as shown in FIG. 7C illustrates a generally rectangular openings 430, it should be appreciated that other shapes, e.g., squares, circles, ovals, polygons, etc, may be employed to form the openings.

It should also be appreciated that other configuration of patterns may be employed besides the one described in FIGS. 7A through 7C.

As shown in FIGS. 7B and 7C, the capacitor electrode 424b and 424c, respectively, may be formed to partially cover the lightly-doped well 422, so as to provide a capacitive increase of the capacitor C_{SCG} from extending a parasitic capacitance between the lightly-doped well 422 and the outer face of the capacitor electrode 424b or 424c. As a result, a dynamic range, e.g., an optical sensing range, of the optical detector 411, e.g., the photosensor, may be enlarged.

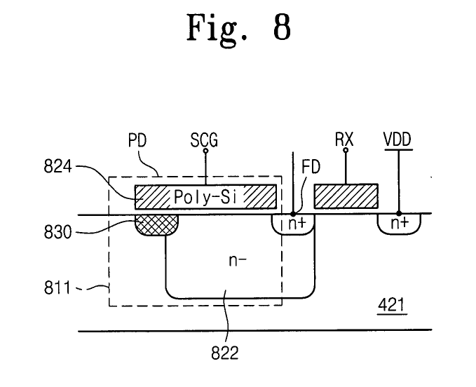

FIG. 8 illustrates a sectional diagram of another structure of the optical detector 811, e.g., photodiode PD, of FIG. 4. FIG. 8 is similar to FIG. 4 except for an additional structure of an impurity-doped region 830.

Referring to FIG. 8, the optical detector 811 may include the additional impurity-doped region 830 in a capacitor electrode 824 of the MOS capacitor C_{SCG} may be operable in the depletion and inversion modes shown in FIG. 6. In detail, the MOS capacitor C_{SCG} may be composed of a first capacitor and a second capacitor. The first capacitor may include a lightly-doped well 822 and the capacitor electrode 824 coupled to the sensitivity control signal SCG, and the second capacitor may include the impurity-doped region 830 and the capacitor electrode 824 coupled to the sensitivity control signal SCG.

By doping the impurity-doped region 830 with N or P-type impurities, the second capacitor including the capacitor electrode 824 and the impurity-doped region 830 may be operable in the inversion mode or the depletion mode. Therefore, the capacitor C_{SCG} may be operable in characteristics between the curve of the P-type MOS capacitor and the curve of the depletion mode shown in FIG. 6. Accordingly, this modified capacitance characteristic may be used in controlling the sensitivity of the pixel.

If the reset control signal RX is high while the row selection signal SEL is high, a voltage level of the node FD may increase, and may be transferred to the node N1 via the transistors M13 and M11. The voltage transferred to the node N1 may be the reset voltage VRES to be transferred to the ADC 130 shown in FIG. 1.

If the reset control signal RX is low while the row selection signal SEL is high, a signal photoelectrically converted by the photodiode PD of the optical detector 411 may be transferred to the node N1 via the transistors M13 and M11. The voltage transferred to the node N1 may be the image signal voltage VSIG.

During this stage, a voltage level of the sensitivity control signal SCG may determine the capacitance C_{MOS} of the MOS capacitor C_{SCG} included in the photodiode PD, which may determine an output gain of the image signal voltage VSIG. For example, an output voltage Vout and a gain ASF of the source follower transistor M13 may be given by the following equation in relation with the capacitance C_{MOS} of the MOS capacitor C_{SCG}:

$$Vout = {A}_{SF} \frac{{i}_{ph} \times T}{Cp + Cmos} \qquad [ Equation 1 ]$$

where Cp is a capacitance of the photodiode PD; iₚₕ is an photoelectrically converted current; and T is an optical accumulation time. The term iₚₕ×T may correspond to an amount of charges (i.e., electrons) generated by the photoelectric conversion from the photodiode PD. Therefore, as shown in Equation 1, the output voltage Vout from the source of the source follower transistor M13 may be varied along capacitance C_{MOS} of the MOS capacitor C_{SCG} determined by a voltage level of the sensitivity control signal SCG.

In the meantime, the ADC 130 may sequentially receive the reset voltage VRES and the image signal voltage VSIG from the node N1, and may output a digital signal corresponding to a difference between the reset voltage VRES and the image signal voltage VSIG. The converted digital signal may be provided to and processed in the digital processor (not shown).

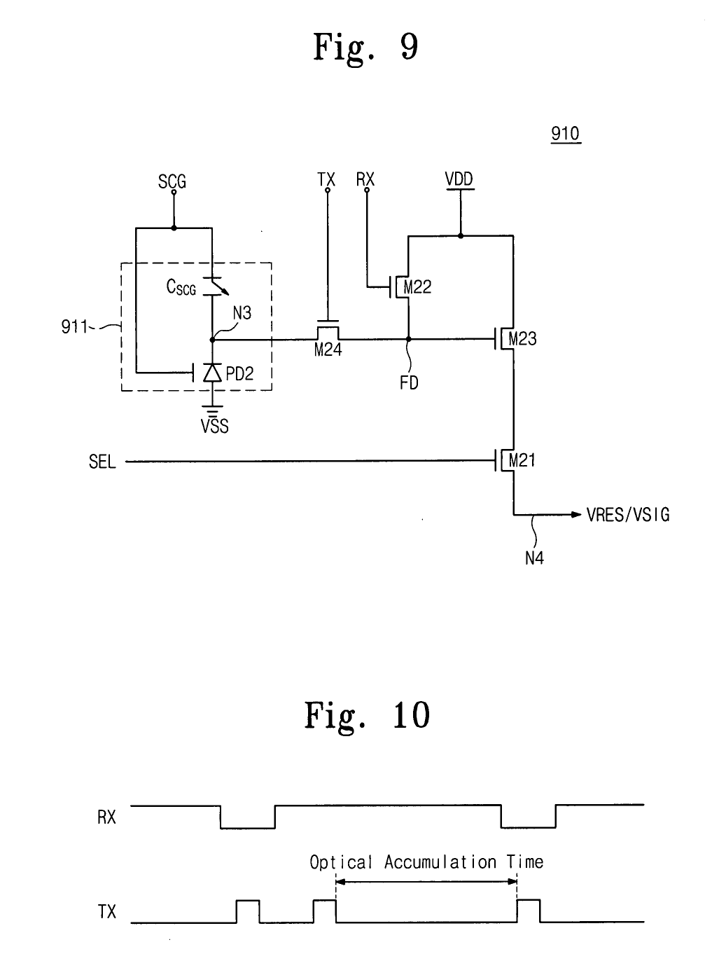

FIG. 9 illustrates a pixel circuit 910 of the CMOS image sensor 100 in accordance with another example embodiment. The pixel circuit 910 may include MOS transistors M21˜M24 and an optical detector, e.g., a photodiode 911. The pixel circuit 910 may be similar to the pixel circuit 410 of FIG. 4, except for an additional MOS transistor M24.

Referring to FIG. 9, the transistors M22 and M24 may be connected between the power source voltage VDD and a node N3 in series. A gate of the transistor M22 may be coupled to a reset control signal RX, and a gate of the transistor M24 may be coupled to a transmission control signal TX. The optical detector 911 connected to the node N3 may include a MOS capacitor C_{SCG} and a photodiode PD2. The optical detector 911 of FIG. 9 may operate in the same manner as the optical detector 411 shown in FIG. 4, and will not be discussed in further detail herein.

The transistors M23 and M21 may be connected between the power source voltage VDD and a node N4 in series. A gate of the transistor M23 may be connected to the node FD connecting the transistors M22 and M24. A gate of the transistor M21 may be coupled to the row selection signal SEL.

FIG. 10 illustrates a timing diagram of reset and transmission control signals, RX and TX, respectively, operating in the pixel circuit 910 shown in FIG. 9.

With reference to FIGS. 9 and 10, a method for operating the pixel circuit 910 will be described herein.

During operation, if the reset control signal RX is high while the selection signal SEL is high, the reset voltage VRES may be output to the node N4. Further, if the transmission control signal TX is high while the reset control signal RX is high, the photodiode PD2 may be reset. Accordingly, the photodiode PD2 may accumulate photoelectrons induced by light, when the reset control signal RX is at high level and the transmission control signal TX is at low level.

Alternatively, if the reset control signal RX is low and the transmission control signal TX is high, a voltage corresponding to the photoelectrons accumulated in the photodiode PD2 may be transferred to the node FD. Accordingly, the voltage of the node FD may be output as the image signal voltage VSIG. Further, a voltage level of the sensitivity control signal SCG may be operated to vary the capacitance CMOS of the MOS capacitor C_{SCG} included in the optical detector 911. By setting voltage level of the sensitivity control signal SCG by pixels at different settings, the pixel circuit 910 may adjust a saturation voltage of the image signal voltage VSIG.

In the figures, the dimensions of elements and regions may be exaggerated for clarity of illustration. It will also be understood that when an element is referred to as being “on”, “connected to” or “coupled to” another element it can be directly on, connected or coupled to the other element or intervening elements may be present. In contrast, when an element is referred to as being “directly on,” “directly connected to” or “directly coupled to” another element, there are no intervening elements present. Further, it will be understood that when an element is referred to as being “under” or “above” another element, it can be directly under or directly above, and one or more elements may also be present. In addition, it will also be understood that when an element is referred to as being “between” two elements, it can be the only element between the two elements, or one or more intervening element may also be present. Like numbers refer to like elements throughout. As used herein, the term “and/or” includes any and all combinations of one or more of the associated listed items.

It will also be understood that, although the terms “first”, “second”, etc. may be used herein to describe various elements, structures, components, regions, layers and/or sections, these elements, structures, components, regions, layers and/or sections should not be limited by these terms. These terms are only used to distinguish one element, structure, component, region, layer and/or section from another element, structure, component, region, layer and/or section. Thus, a first element, structure, component, region, layer or section discussed below could be termed a second element, structure, component, region, layer or section without departing from the teachings of exemplary embodiments.

Spatially relative terms, such as “beneath,” “below,” “lower,” “above,” “upper” and the like, may be used herein for ease of description to describe one element or feature relationship to another element(s) or feature(s) as illustrated in the figures. It will be understood that the spatially relative terms are intended to encompass different orientations of the device in use or operation in addition to the orientation depicted in the figures. For example, if the device in the figures is turned over (or upside down), elements or features described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A pixel structure of a CMOS image sensor, comprising:
a substrate of a first-conductivity;
a photodiode region of a second conductivity in the first-conductivity substrate;
a transfer gate on the first-conductivity substrate; and
a capacitor electrode on the second-conductivity photodiode region.

2. The pixel structure as claimed in claim 1, wherein the capacitor electrode substantially covers the second-conductivity photodiode region.

3. The pixel structure as claimed in claim 1, wherein the capacitor electrode partially covers the second-conductivity photodiode region.

4. The pixel structure as claimed in claim 3, wherein the second-conductivity photodiode region is partially covered in a bi-directionally extending form of fingers.

5. The pixel structure as claimed in claim 3, wherein the second-conductivity photodiode region is partially covered with a plurality of openings.

6. The pixel structure as claimed in claim 1, wherein the capacitor electrode is formed of a transparent conductive film coupled to a sensitivity control signal.

7. The pixel structure as claimed in claim 6, wherein the transparent conductive film is polysilicon.

8. The pixel structure as claimed in claim 1, further comprising a floating diffusion layer adjacent to the second-conductivity photodiode region.

9. The pixel structure as claimed in claim 1, further comprising a dielectric film on the second-conductivity photodiode region, and the capacitor electrode is positioned on the dielectric film.

10. The pixel structure as claimed in claim 1, wherein the pixel structure is a pixel circuit.

11. The pixel structure as claimed in claim 10, wherein the pixel circuit further includes:
a first transistor connected to a first node through one of source and drain electrodes and to an output node through the other source and drain electrodes, and receives a row selection signal through a gate electrode;
a second transistor connected to a first voltage through one of the source and drain electrodes and to a second node through the other source and drain electrodes, and receives a reset control signal through a gate electrode;
a third transistor connected to a first power source through one of the source and drain electrodes to the first node through the other source and drain electrodes, and to the second node through a gate electrode; and
a photodiode connected between a second voltage and the second node, to conduct a photoelectric conversion.

12. A method of forming a pixel structure in a CMOS image sensor, comprising:
forming a substrate of a first-conductivity;
forming a photodiode region of a second-conductivity in the first-conductivity substrate; and
forming a capacitor electrode on the second-conductivity photodiode region.

13. The method as claimed in claim 12, wherein the capacitor electrode substantially covers the second-conductivity photodiode region.

14. The method as claimed in claim 12, wherein the capacitor electrode partially covers the second-conductivity photodiode region.

15. The method as claimed in claim 12, wherein the capacitor electrode is formed of a transparent conductive film coupled to a sensitivity control signal, the transparent conductive film is polysilicon.

16. The method as claimed in claim 12, further comprising forming a dielectric film on the second-conductivity photodiode region, and forming the capacitor electrode on the dielectric film.

17. The method as claimed in claim 12, further comprising:
connecting a first transistor to a first node through one of source and drain electrodes and to an output node through the other source and drain electrodes, and receives a row selection signal through a gate electrode;
connecting a second transistor to a first voltage through one of the source and drain electrodes and to a second node through the other source and drain electrodes, and receives a reset control signal through a gate electrode;
connecting a third transistor to a first power source through one of the source and drain electrodes to the first node through the other source and drain electrodes, and to the second node through a gate electrode; and
connecting a photodiode between a second voltage and the second node, to conduct a photoelectric conversion.
